(19) United States
(12) Patent Application Publication
(10) Pub. No.: US 2006/0282720 A1
(43) Pub. Date: Dec. 14, 2006

(54) Method for the automatic provision of repair position data of fuse elements in integrated memory circuit

(76) Inventors: Markus Hofsaess, Munich (DE); Bermherd Ruf, Sauerlach (DE); Florian Schnabel, Hoehenkirchen (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/396,952

(22) Filed: Apr. 3, 2006

(30) Foreign Application Priority Data
Apr. 1, 2005 (DE) 102005015002.0-55

(51) Int. Cl. G11C 29/00

(52) U.S. Cl. 714/718

(57) ABSTRACT

Methods and systems for the determination of the function and of the position information of fuses from a schematic and/or a network list and a layout. A repair process is aided with this position information.

### CROSS-REFERENCE TO RELATED APPLICATIONS

This application claims foreign priority benefits under 35 U.S.C. §119 to co-pending German patent application number DE 10 2005 015 002.0-55, filed 1 Apr. 2005. This related patent application is herein incorporated by reference in its entirety.

### BACKGROUND OF THE INVENTION

1. Field of the Invention

The invention relates to a method and system for providing repair position data which indicates the position of fuse elements to be programmed in an integrated memory circuit. The repair data provided indicates which address of a regular storage area is to be replaced by an address of a redundant storage area of the integrated memory circuit.

2. Description of the Related Art

With the aid of fuse elements, faulty regular storage areas in integrated memory circuits are repaired, so that when the corresponding address is applied, instead of the regular storage areas, the redundant storage area is addressed. For this purpose, the fuse elements in the integrated circuits are normally programmed when the memory circuit is still in the unsawn state (on a wafer).

The fuse elements typically used are laser fuse elements. A laser fuse element is typically formed as a metallic conductor track which, with the aid of a laser, can be severed in a laser trimming process. The laser fuse element thus serves as a switch and, together with a latch, forms a programmable storage element which provides a datum with which specific circuits of the integrated memory circuit can be activated or deactivated.

The laser trimming device used for programming the laser fuse elements has to be provided with repair position data, that is to say the fuse coordinates which indicate the exact absolute or relative geometric position of the laser fuse elements to be programmed on the substrate wafer.

During the design of an integrated circuit, firstly a schematic is drawn up, which is a schematic drawing of a circuit. The schematic includes the symbols for all the components used (resistors, transistors, lines and so on) and their designations. From the schematic, a network list is generated which describes the wiring of electronic components at the circuit level in an abstract (alphanumeric) form.

In a following layout process, the components are placed virtually on the substrate surface and connected to one another by means of connecting lines (place and route process), as predefined accordingly by the schematic or the network list. In this way, the layout is produced, which shows the arrangement and connection of the individual electronic components on the substrate. On the basis of the layout, the memory circuits are produced in an integrated way in a manufacturing process.

During the placement of the electronic components predefined by the network list, the necessary fuse elements are also positioned on the substrate surface. In order to determine the position of the individual fuse elements, hitherto the relevant fuse elements were read out from the layout of the integrated memory circuit, partly by hand and partly automatically. Then, for a large number of the fuse elements, the associated circuit functions have to be determined manually from the layout, since there is no direct relationship between a position in the layout and a corresponding function of the circuit part in the basic schematic (network list). However, the manual determination of the positions of the fuse elements is time-consuming and, in particular, susceptible to error, since determining the function of a specific fuse element is carried out by following the line paths in the layout until a defined point in the layout is reached which can be allocated unambiguously to a point in the schematic (network list) and therefore to its circuit function.

In addition, the fuse elements with which the redundancy of the integrated memory circuit is implemented are generally likewise determined manually from the layout, typically as reference coordinates of fuse elements groups having a plurality of fuse elements. The number of fuse elements present in a group of fuse elements, and also the distance between the fuse elements, must likewise be determined manually from the layout.

From these redundant fuse elements and what are known as trimming fuse elements for carrying out other adjustments in the memory circuit, what is known as a fuse element table is generated, in which the function of the respective fuse element and its corresponding position on the integrated circuit are associated with each other.

With the aid of a fuse converter and by using repair data which is provided and which specifies which of the fuses are to be programmed, the fuse elements table is also used to generate repair position data, which specifies at which position the laser fuse elements to be programmed are located.

Therefore, there is a need to provide a method for providing repair position data of fuse elements for the repair of an integrated memory circuit which can be carried out in an automated manner.

### SUMMARY OF THE INVENTION

According to a first aspect of the present invention, a method for repairing a memory circuit with the aid of a repair process is provided, in which fuse elements determined by means of repair position data in an integrated memory circuit are programmed. The repair position data depends on repair data, which specifies which address of a regular storage area is to be replaced by an address of a redundant storage area in order to address the redundant storage area when the address of the regular storage area is applied.

In the method, firstly a network list is provided, which describes the wiring of electronic components and fuse elements in the memory circuit. The network list is generated, for example, from the schematic drawn up previously.

A fuse identifier is allocated to each of the fuse elements by using the network list, for the purpose of unambiguous identification of the fuse elements.

An item of address information is allocated to a group of the fuse elements designated by the fuse identifiers, the item of address information indicating which of the redundant storage areas is associated with the group of fuse elements.

Layout data is then generated from the network list. In the process, position data of the fuse elements is extracted from the layout data and a link with the network list is determined with the aid of the fuse identifiers.

Between the address information of the respective fuse elements and the position data, an association is determined by using the fuse identifier. In this case, the addresses are derived from the information contained in the fuse identifiers, whereas the position data of the fuse elements is allocated with the aid of the link with the network list (LVS database).

Repair data is then obtained, for example from a tester device. From the repair data, repair position data is determined, the repair position data specifying at which position the laser fuse elements to be programmed are located. The laser fuse elements determined by means of the repair position data are then programmed in order to repair the memory circuit.

Provision can be made for the determination of the repair position data to comprise logical linking of an address of the redundant storage area with the address of the storage area to be replaced, the repair position data being determined on the basis of the result of the logical linking, the position data and the fuse identifier.

According to a further embodiment of the invention, additional repair position data is added to the repair position data determined on the basis of the result of the logical linking, the position data and the fuse identifier.

A particular embodiment provides a method for repairing a memory circuit with the aid of a repair process, in which fuse elements determined by means of repair position data in an integrated memory circuit are programmed, the method including: providing a network list which describes the wiring of electronic components and fuse elements in the memory circuit, allocating a respective fuse identifier to the fuse elements by using the network list for the purpose of unambiguous identification of the fuse elements, assigning an item of address information to a group of the fuse elements designated by the fuse identifiers, the item of address information indicating which of the redundant storage areas is associated with the group of fuse elements, generating layout data from the network list, extracting position data of the fuse elements from the layout and determining a link with the network list with the aid of the fuse identifiers, generating an association between the address information of the respective fuse elements and the position data by using the link with the network list, obtaining the repair data from a tester device; determining repair position data from the repair data, the repair position data indicating at which position the fuse elements to be programmed are located, and programming the fuse elements determined by the repair position data in order to repair the memory circuit.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a flow chart illustrating a method for determining repair position data, and

FIG. 2 shows, by way of example, a hierarchical tree for a network list for fuse elements, with which individual parts of a memory cell array can be replaced by redundant lines.

### DETAILED DESCRIPTION OF THE PREFERRED EMBODIMENT

During the manufacture of integrated memory circuits, it is possible for defects to occur which can be repaired by a repair method. For this purpose, redundant storage areas are provided in the integrated memory circuit and can be activated in order, when addressing a regular storage area, to address a redundant storage area instead. In order to activate redundant storage areas, what are known as laser fuse elements are normally used which, following the manufacture of the integrated memory circuit, can be programmed in a laser trimming process, by conductor tracks being severed or not severed. Since, in the case of conventional methods, after the creation of the layout there is no position information about the geometric position of the fuse elements, which information permits assignment of a specific one of the fuse elements to the address of the redundant storage area, hitherto the necessary position information had to be determined manually from the layout. The method according to embodiments of the invention relates to the automatic determination of the function and of the position information from the schematic and/or the network list and the layout, and the performance of the repair process with the aid of this position information.

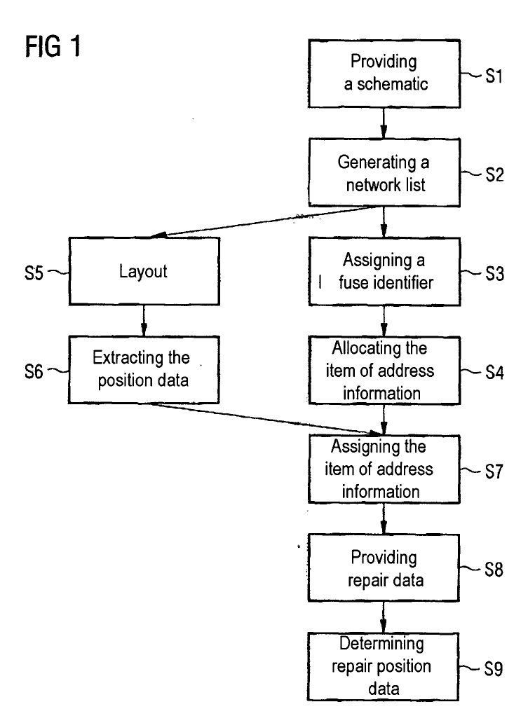

FIG. 1 illustrates a flow chart relating to the progress of the method according to one embodiment of the invention. Following the schematic design of an integrated memory circuit in the form of what is known as a schematic (step S1), what is known as a network list is generated (step S2), which describes the electrical design of a circuit at the circuit level. This network list is an abstract (alphanumeric) description of the schematic which includes the electrical wiring of the components. As a rule, the schematic does not contain any information as to how the electronic components are subsequently arranged geometrically on the substrate surface during the integrated manufacture. The network list generated from the schematic is typically built up hierarchically since it is frequently the case that identical circuits with identical function are used repeatedly for the integrated circuits and are thus implemented repeatedly at different locations.

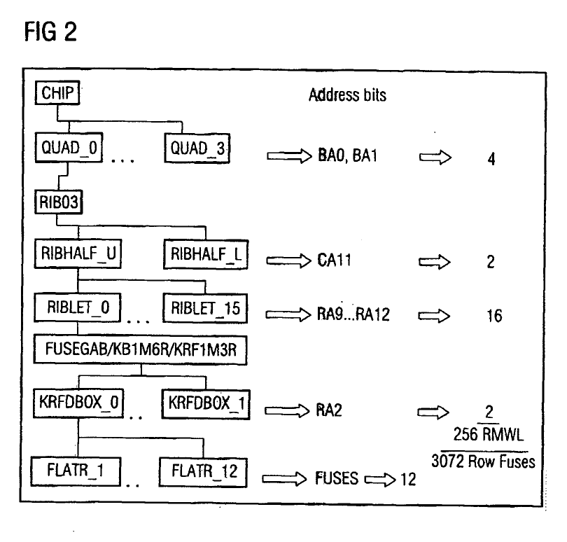

A possible hierarchical structure of a network list is shown in FIG. 2 in the form of a hierarchical tree for redundant fuse elements of the memory circuit. The redundant fuse elements are bundled into fuse element groups and are used to replace one line of memory elements in the memory circuit by one line of redundant memory elements. In the event of defective memory cells along a word line or a bit line, the redundant fuse elements are used for the purpose of replacing the corresponding word line or bit line with a redundant word line or bit line. The number of redundant fuse elements in this case corresponds substantially to the bit length of the address of the word line or bit line. The redundant fuse elements belonging to a redundant word line or bit line are in each case combined into a fuse element group, which is assigned a uniform address for the redundant storage area.

The circuit is previously created in such a way that each fuse element or, under certain circumstances, a correspondingly contiguous group of fuse elements in an individual fuse elements block, is given an individual designation with respect to the corresponding hierarchical branch. Thus, in step S3, each redundant fuse element can be assigned an unambiguous fuse identifier, which identifies each of the redundant fuse elements in the fuse element blocks unambiguously, by the path name of the hierarchical branch being used as a designation of the respective fuse element and as a reference to its function in the memory circuit. Since the hierarchical path has a direct relationship with the electrical significance of the fuse elements, in the case of redundant fuse elements, the significance also corresponds to the address of the redundant storage area (redundant address) generated from the hierarchical path.

An address typically designates a group of fuse elements in a group. Within the group, the individual fuse elements can also be designated by a further number (e.g. the address bit), in order to identify it unambiguously.

The network list can be provided hierarchically as a hierarchical tree, the hierarchical tree having hierarchical branches which in each case correspond to a fuse element. The allocation of fuse identifiers to each of the fuse elements may be carried out by using the schematic and/or the network list for the purpose of unambiguous identification of the fuse elements, by the fuse identifier being defined on the basis of the associated hierarchical branch.

This makes it possible to determine the function (address bit of the address information of the storage area to be replaced) of the individual fuse elements in that, with the aid of the hierarchical structure of the network list and the hierarchical branch in the network list, the fuse element is identified unambiguously. This means that the fuse elements or a group of fuse elements are given a unique address, which is derived from the hierarchical path. Since the hierarchical branch also contains the information about the electrical significance (address bit or function) of the fuse element, with the aid of the geometric position data of the fuse elements, the associated function of the individual fuse elements and the repair data, the repair position data can be determined with which the fuse elements can be programmed, for example with the aid of a laser trimming device. By means of the determination of the function of the individual fuse elements by using the hierarchical branch of the network list, manual allocation of the function of the fuse elements in the layout is dispensed with, which means that errors can be avoided and the determination of repair position data can be accelerated considerably.

FIG. 2 illustrates an example of the hierarchical tree of the network list for the redundant fuse elements for a word line, from which the fuse identifiers for the redundant fuse elements can be derived.

The arrangement of the individual bits of the fuse identifier is predefined in a bit string. The designations of the individual bits, e.g. CA11, are previously defined unambiguously. In the example indicated, a bit stream has a length of 32 bits, in which individual bits can be unoccupied. The sequence for a bit string to be extracted could, for example, run as follows:
RA0, RA1, RA2, RA3, RA4, RA5, RA6, RA7, RA8, RA9, RA10, RA11, RA12, CA11, DO0, DO1, DO2, ST0, ST1, ST2, BA0, BA1, BA2, RC=1, S=0, --, --, --, --.
   The fuse identifier, for example for a fuse element
CHIP/QUAD_{—}3/RIB03/RIBHALF_U/RIBLET_{—}1/KRFDBOX_{—}1 then results in the binary string:
   00100000010000000000000010000000.

On account of the arrangement (function) of the fuse element blocks in the overall memory circuit, each fuse element block can be allocated an item of address information (step 4). The item of address information indicates which of the redundant storage areas (in this case which line having redundant storage elements) is assigned to the fuse element group of the corresponding fuse element block. Thus, each of the fuse identifiers can also be allocated the corresponding item of address information.

During the laying-out, a real circuit is designed from the network list (step S5), as to be found later on the substrate. Here, the components and their wiring, as are illustrated in the schematic, are placed virtually in a geometrically correct manner on the surface of the integrated circuit. The laying-out can be carried out by using the network list generated from the schematic.

Together with or following the creation of the layout, an extraction (LVS) is carried out (step S6), by which means the position data of the individual fuse elements is obtained. The extraction is carried out by comparing the geometric structures of the layout with reference structures which correspond to the patterns of the fuse elements to be found or the circuit structures, such as latches, generally used with them. As the result of the extraction, what is known as an LVS database is obtained, which describes an assignment of the geometric positions of the fuse elements to the fuse identifiers and thus to the individual fuse elements.

In general, position data of the fuse elements is extracted from the layout data and a link with the network list is determined with the aid of the fuse identifiers. This link is also designated in the LVS database. For this purpose, geometric data can be extracted from the layout and compared with corresponding predefined geometric pattern data of circuit elements (in this case the fuse elements or latches associated with the latter). By means of coincidences, the geometric position data can then be allocated to the corresponding circuit elements. This information is then reconciled with the network list, so that an unambiguous association is produced.

It is therefore possible, in a following step S7, to generate an association between the item of address information of the respective fuse elements of a fuse element block and the position data of the fuse elements, so that the respective function (address bit of the address of the redundant storage area) of each individual fuse element is connected to the respective item of position data which indicates the geometric position of the relevant fuse element.

During the testing of the memory circuit with the aid of a tester device, repair data is obtained (step S8) if a defect has been detected during the testing of the integrated memory circuit. The repair data designates the address of a defective storage area and indicates, in particular via a line address or column address, which storage area is to be replaced in order to repair the defect found.

From the repair data, repair position data can be determined (step 9), which indicates at which physical position on the substrate wafer having the integrated memory circuits the laser fuse elements to be programmed, that is to say the laser fuse elements to be severed, are located. With the aid of the repair position data, the specific fuse elements can then be programmed by means of severing or not severing, for example with the aid of what is known as a laser trimming device.

In order to determine repair position data, addresses of regular storage areas in which a defect has occurred and redundant storage areas are used in order to generate fuse information. The fuse information indicates which of the redundant fuse elements in a group are programmed and which are not.

On an integrated circuit there is only a limited number of redundant word and bit lines, which is many times lower than the number of the actual word and bit lines. Each fuse element group is therefore permanently assigned a redundant address, the fuse element group being assigned to any desired regular word line or bit line. By means of suitable programming (blowing) of the fuse elements, for example with a laser trimming device, a defective word line or bit line is replaced by a corresponding redundant word line or bit line respectively assigned to the fuse elements.

Which of the fuse elements of a fuse element group is to be programmed in order to replace a specific word line results in accordance with possible wiring of the fuse elements from a logical combination, in particular an exclusive OR combination of the address of the word line and the address of the redundant word line, as can be seen from the example shown in the following table.

| | Addr. bits | | | | | | | | |
|---|---|---|---|---|---|---|---|---|---|
| | 0 | 1 | 2 | 3 | 4 | 5 | 6 | 7 | 8 |
| WL | 0 | 1 | 1 | 0 | 0 | 1 | 1 | 0 | 0 |
| RWL | 0 | 0 | 1 | 1 | 0 | 0 | 0 | 1 | 0 |
| XOR | 0 | 1 | 0 | 1 | 0 | 1 | 1 | 1 | 0 |

While the redundant address has hitherto been determined manually from the layout, it is now possible in the invention to derive the redundant addresses from the hierarchical branches of the fuse elements in the network list. For this purpose, the nodes in the hierarchical tree of the network list shown in FIG. 2 which indicate the function of the individual fuse elements are allocated address regions.

The method according to embodiments of the invention for determining the repair position data for the programming of laser fuse elements advantageously makes use of the possibility of producing a connection between the network list and the layout. As a result, a fuse element and the fuse element block of the network list belonging to the fuse element can be allocated an exact position (i.e., a coordinate) of the fuse element in the layout. In order to determine the repair position data in an automated way, each of the fuse elements is also described in a suitable way, so that they can be determined exactly through the repair data which is made available by the tester device.

This suitable description is obtained by the hierarchy of the fuse element blocks being used in order to identify each fuse element unambiguously by using its position in the hierarchy branch of the network list. At the same time, the hierarchical branch of the individual fuse elements also contains the information about the function and electrical significance of the fuse element. From this hierarchical branch, in conjunction with a suitable mapping table, an address for the fuse element is then generated, which includes the electrical significance (bit position of the storage address to be replaced) of the fuse element. The address, together with a translation table, can be matched to the requirements of the tester device.

With respect to further fuse elements not provided for redundancy purposes in the integrated memory circuit, specifically the trimming and special fuse elements, their position data is likewise extracted from the layout with the aid of the extraction. By contrast, their functions and electrical significances are determined in an empirical way, and stored in a suitable mapping table, so that, by linking the position data with corresponding setting data with the aid of the mapping table, corresponding further repair position data can be determined.

In the process, position data of the fuse elements is extracted from the layout data and a link with the network list is determined with the aid of the fuse identifiers.

By means of the method according to embodiments of the invention, the process of the determination of repair position data with the aid of repair data determined by the tester device can be carried out in an automated manner. As a result, the manual allocation of the function and of the electrical significance for the fuse element is rendered superfluous, and a considerable time saving can be realized. A further important advantage in the automatic performance of the allocation of the function of the fuse elements is relatively higher reliability.

In general, the method according to embodiments of the invention contains a new approach to the generation of the repair position data, an association between the fuse elements provided in the network list and the fuse elements positioned in the layout being generated in an automated manner. Furthermore, by means of the association of the redundant storage area that can be addressed through the fuse element, an exact geometric position of the fuse element in the layout is allocated, so that the function of each of the fuse elements is known.

While the foregoing is directed to embodiments of the present invention, other and further embodiments of the invention may be devised without departing from the basic scope thereof, and the scope thereof is determined by the claims that follow.

What is claimed is:

1. A method for repairing a memory circuit with the aid of a repair process utilizing a tester device, comprising:
providing a network list which describes electrical wiring of electronic components and fuse elements in the memory circuit;
allocating a respective fuse identifier to each fuse element utilizing the network list which provides unambiguous identification of the fuse elements;
assigning an item of address information to a group of the fuse elements designated by a respective fuse identifier, the item of address information indicating a respective redundant storage area associated with the group of fuse elements;
generating layout data from the network list;
extracting respective position data of the fuse elements from the layout data and determining a link with the network list utilizing the fuse identifiers;
generating an association between the address information of the respective fuse elements and the position data utilizing the link with the network list;
obtaining the repair data from the tester device;
determining repair position data from the repair data, the repair position data indicating at which position the fuse elements to be programmed are located, the repair position data depending on repair data which specifies which address of a regular storage area is to be replaced by an address of the redundant storage area in order to address the redundant storage area when the address of the regular storage area is applied; and
programming the fuse elements determined by the repair position data to repair the memory circuit.

2. The method of claim 1, wherein extracting respective position data of the fuse elements comprises:
comparing the layout with one of:
an item of geometric pattern data for a respective fuse element; and
a circuit associated with the fuse element; and
in the event of coincidence, determining a geometric position of a corresponding fuse element in the layout.

3. The method of claim 2, wherein determining the repair position data comprises:
logically linking an address of the redundant storage area with the address of the storage area to be replaced; and
determining the repair position data based on a result of the logical linking, the position data and the fuse identifiers.

4. The method of claim 3, wherein determining the repair position data further comprises:
adding further repair position data to the repair position data determined based on a result of the logical linking, the position data and the fuse identifiers.

5. The method of claim 4, wherein the network list is provided hierarchically as a hierarchical tree which has hierarchical branches, wherein each hierarchical branch corresponds to a corresponding fuse element, wherein the allocation of fuse identifiers to the fuse elements is carried out utilizing the network list for the unambiguous identification of the fuse elements, and wherein the fuse identifier is defined on the basis of the associated hierarchical branch.

6. The method of claim 1, wherein the network list is provided hierarchically as a hierarchical tree which has hierarchical branches, wherein each hierarchical branch corresponds to a corresponding fuse element, wherein the allocation of fuse identifiers to the fuse elements is carried out utilizing the network list for the unambiguous identification of the fuse elements, and wherein the fuse identifier is defined on the basis of the associated hierarchical branch.

7. The method of claim 2, wherein the network list is provided hierarchically as a hierarchical tree which has hierarchical branches, wherein each hierarchical branch corresponds to a corresponding fuse element, wherein the allocation of fuse identifiers to the fuse elements is carried out utilizing the network list for the unambiguous identification of the fuse elements, and wherein the fuse identifier is defined on the basis of the associated hierarchical branch.

8. The method of claim 3, wherein the network list is provided hierarchically as a hierarchical tree which has hierarchical branches, wherein each hierarchical branch corresponds to a corresponding fuse element, wherein the allocation of fuse identifiers to the fuse elements is carried out utilizing the network list for the unambiguous identification of the fuse elements, and wherein the fuse identifier is defined on the basis of the associated hierarchical branch.

9. A method for determining a function and position information of fuse elements in a memory circuit, comprising:
allocating a respective fuse identifier to each of a plurality of fuse elements utilizing a network list which provides unambiguous identification of the fuse elements;
assigning an item of address information to a group of the fuse elements designated by the respective fuse identifier, the item of address information indicating a respective redundant storage area associated with the group of fuse elements;
generating layout data from the network list;
extracting respective position data of the fuse elements from the layout data;
determining a link of the respective position data of the fuse elements from the layout data with the network list utilizing the fuse identifiers; and
generating an association between the address information of the respective fuse elements and the position data utilizing the link with the network list.

10. The method of claim 9, wherein the network list describes electrical wiring of electronic components and the fuse elements in the memory circuit.

11. The method of claim 10, wherein the network list is provided hierarchically as a hierarchical tree which has hierarchical branches, wherein each hierarchical branch corresponds to a corresponding fuse element, wherein the allocation of fuse identifiers to the fuse elements is carried out utilizing the network list for the unambiguous identification of the fuse elements, and wherein the fuse identifier is defined on the basis of the associated hierarchical branch.

12. The method of claim 10, wherein extracting respective position data of the fuse elements comprises:
comparing the layout with one of:
an item of geometric pattern data for a respective fuse element; and
a circuit associated with the fuse element; and
in the event of coincidence, determining a geometric position of a corresponding fuse element in the layout.

13. The method of claim 12, wherein determining the repair position data comprises:
logically linking an address of the redundant storage area with the address of the storage area to be replaced; and
determining the repair position data based on a result of the logical linking, the position data and the fuse identifiers.

14. The method of claim 13, wherein determining the repair position data further comprises:
adding further repair position data to the repair position data determined based on a result of the logical linking, the position data and the fuse identifiers.

15. The method of claim 14, wherein the network list is provided hierarchically as a hierarchical tree which has hierarchical branches, wherein each hierarchical branch corresponds to a corresponding fuse element, wherein the allocation of fuse identifiers to the fuse elements is carried out utilizing the network list for the unambiguous identification of the fuse elements, and wherein the fuse identifier is defined on the basis of the associated hierarchical branch.
